(19) United States
(12) Patent Application Publication
(10) Pub. No.: US 2023/0259028 A1
(43) Pub. Date: Aug. 17, 2023

(54) RESIST UNDERLAYER FILM-FORMING COMPOSITION CONTAINING REACTION PRODUCT OF HYDANTOIN COMPOUNDS

(71) Applicant: NISSAN CHEMICAL CORPORATION, Tokyo (JP)

(72) Inventors: Ryuta MIZUOCHI, Toyama-shi (JP); Yuki KATO, Toyama-shi (JP); Mamoru TAMURA, Toyama-shi (JP)

(73) Assignee: NISSAN CHEMICAL CORPORATION, Tokyo (JP)

(21) Appl. No.: 18/009,874

(22) PCT Filed: Jul. 28, 2021
(86) PCT No.: PCT/JP2021/027814

§ 371 Date: Dec. 12, 2022

(30) Foreign Application Priority Data
Jul. 29, 2020 (JP) 2020-127927

(51) Int. Cl. G03F 7/039; G03F 7/20; C08G 73/06; H01L 21/027; H01L 21/311; H01L 21/3065; H01L 21/308

(52) U.S. Cl. CPC G03F 7/0395; G03F 7/0397; G03F 7/2004; C08G 73/0677; H01L 21/0275; H01L 21/31138; H01L 21/31144; H01L 21/3065; H01L 21/3081; H01L 21/3088; H01L 21/3086; H01L 21/31122; H01L 21/32139

(57) ABSTRACT

A composition for forming a resist underlayer film that enables the formation of a desired resist pattern; and a method for producing a resist pattern and a method for producing a semiconductor device, each of which uses the resist underlayer film-forming composition. The resist underlayer film-forming composition comprises an organic solvent and the reaction product of (A) a hydantoin-containing compound that has two epoxy groups and (B) a hydantoin-containing compound different from (A). This reaction product is preferably the reaction product of a secondary amino group present in the hydantoin-containing compound (B) and the epoxy group present in the hydantoin-containing compound (A).

### TECHNICAL FIELD

The present invention relates to a composition used in a lithography process, particularly in a leading-edge (for example, ArF, EUV or EB) lithography process, for semiconductor production. The present invention also relates to the application of a resist underlayer film from the composition to a method for producing a resist-patterned substrate, and to a method for manufacturing a semiconductor device.

### BACKGROUND ART

The manufacturing of semiconductor devices has conventionally involved lithographic microprocessing using a resist composition. In the microprocessing, a thin film of a photoresist composition is formed on a semiconductor substrate such as a silicon wafer, and the formed film is irradiated with an active ray such as ultraviolet light through a mask pattern for drawing a device pattern. The latent image is then developed, and the substrate is etched while using the thus-obtained photoresist pattern as a protective film, thereby forming fine irregularities corresponding to the pattern on the substrate surface. Due to the recent increase in the packing density of semiconductor devices, as an active rays, EUV light (extreme ultraviolet light, 13.5 nm wavelength) and EB (electron beam) have been studied for practical use in the leading-edge microprocessing, in addition to the conventionally used i-ray (365 nm wavelength), KrF excimer laser beam (248 nm wavelength) and ArF excimer laser beam (193 nm wavelength). Along with this trend, the influence of semiconductor substrates to the resists has become a big problem.

In order to solve the above problem, there has been made a wide variety of approach of providing a resist underlayer film between a resist and a semiconductor substrate.

Patent Literature 1 discloses a resist underlayer film-forming composition that contains a compound having a hydantoin ring. Patent Literature 2 discloses an EUV lithographic resist underlayer film-forming composition that contains a polymer from the condensation of barbital and an isocyanuric acid-containing compound. Patent Literature 3 discloses a lithographic resist underlayer film-forming composition that contains a polymer having a sulfonyl-containing structure at a terminal of the polymer chain.

### CITATION LIST

### Patent Literature

Patent Literature 1: WO 2018/012253
Patent Literature 2: WO 2013/018802
Patent Literature 3: WO 2015/163195

### SUMMARY OF INVENTION

### Technical Problem

The properties required to a resist underlayer film are that the resist underlayer film is not intermixed with a resist film formed thereon (is insoluble in a resist solvent) and that the dry etching rate is higher than that of a resist film, for example.

In EUV lithography, the line width of a resist pattern that is formed is 32 nm or less. Thus, a resist underlayer film for EUV exposure is formed with a smaller film thickness than conventional. It has been difficult to form such a thin uniform film free from defects, since such a film tends to have pinholes and aggregations due to the influence of, for example, the substrate surface and the polymer that is used.

Meanwhile, in the formation of a resist pattern, a resist is sometimes developed by removing unexposed portions of the resist film with a solvent, usually an organic solvent, capable of dissolving the resist film, thus leaving the exposed portions of the resist film as a resist pattern. In such a negative development process, the major challenge resides in improving the adhesion of the resist pattern.

Moreover, there are demands for formation of a resist pattern with a good rectangular shape while suppressing the deterioration in LWR (line width roughness, variation (roughness)) in line width) at the time of resist pattern formation, and for enhancement of the resist sensitivity.

Objects of the present invention are to provide a composition for forming a resist underlayer film that permits formation of a desired resist pattern, and to provide a resist pattern forming method using the resist underlayer film-forming composition, thereby solving the problems discussed above.

### Solution to Problem

The present invention embraces the following.

[1] A resist underlayer film-forming composition comprising:

an organic solvent; and a reaction product of:

(A) a hydantoin-containing compound having two epoxy groups, with

(B) a hydantoin-containing compound different from (A).

[2] The resist underlayer film-forming composition according to [1], wherein the reaction product is a product of a reaction between a secondary amino group of the hydantoin-containing compound (B) and an epoxy group of the hydantoin-containing compound (A).

[3] The resist underlayer film-forming composition according to [1], wherein compound (A) is represented by formula (A-1), and compound (B) is represented by formula (B-1):

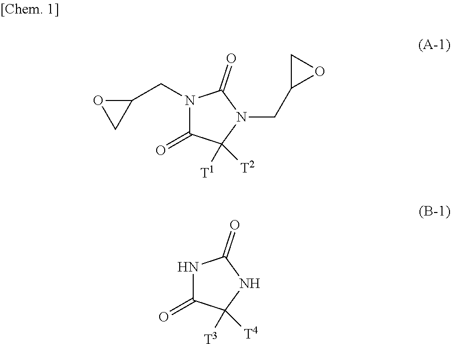

[in formula (A-1) and formula (B-1), T¹, T², T³ and T⁴ each independently denote a hydrogen atom, a C1-C10 alkyl group optionally interrupted by an oxygen atom or a sulfur atom and optionally substituted with a hydroxy group, a C6-C40 aryl group optionally substituted with a hydroxy group, or a C3-C6 alkenyl group].

[4] The resist underlayer film-forming composition according to any one of [1] to [3], wherein the reaction product has a terminal capped with a compound having a functional group.

[5] The resist underlayer film-forming composition according to [4], wherein the functional group is selected from a carboxy group, a hydroxy group, an amino group, an imino group and a thiol group.

[6] The resist underlayer film-forming composition according to [4], wherein the compound having a functional group contains an aliphatic ring optionally interrupted by a heteroatom at a carbon-carbon bond and optionally substituted with a substituent.

[7] The resist underlayer film-forming composition according to [4] or [5], wherein the terminal capped with the compound having a functional group has a structure represented by formula (1) and formula (2):

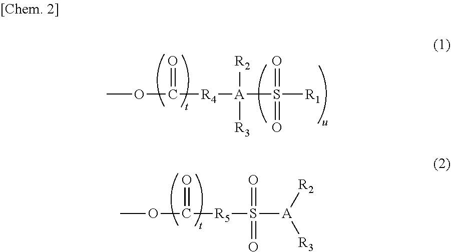

(in formula (1) and formula (2), R₁ denotes an optionally substituted C1-C6 alkyl group, a phenyl group, a pyridyl group, a halogeno group or a hydroxy group; R₂ denotes a hydrogen atom, a C1-C6 alkyl group, a hydroxy group, a halogeno group or an ester group represented by —C(═O)O—X, where X denotes an optionally substituted C1-C6 alkyl group; R₃ denotes a hydrogen atom, a C1-C6 alkyl group, a hydroxy group or a halogeno group; R₄ denotes a direct bond or a C1-C8 divalent organic group; R₅ denotes a C1-C8 divalent organic group; A denotes an aromatic ring or an aromatic heterocyclic ring; t denotes 0 or 1; and u denotes 1 or 2).

[8] The resist underlayer film-forming composition according to any one of [1] to [7], further comprising an acid generator.

[9] The resist underlayer film-forming composition according to any one of [1] to [8], further comprising a crosslinking agent.

[10] The resist underlayer film-forming composition according to any one of [1] to [9], which is an electron beam or EUV resist underlayer film-forming composition.

[11] A resist underlayer film comprising a baked product of a coating film comprising the resist underlayer film-forming composition according to any one of [1] to [10].

[12] A method for producing a patterned substrate, comprising the steps of:

applying the resist underlayer film-forming composition according to any one of [1] to [10] onto a semiconductor substrate followed by baking to form a resist underlayer film;

applying a resist onto the resist underlayer film followed by baking to form a resist film;

exposing the semiconductor substrate coated with the resist underlayer film and the resist; and

developing the exposed resist film followed by patterning.

[13] A method for manufacturing a semiconductor device, comprising the steps of:

forming on a semiconductor substrate a resist underlayer film comprising the resist underlayer film-forming composition according to any one of [1] to [10];

forming a resist film on the resist underlayer film;

forming a resist pattern by applying a light or electron beam to the resist film followed by development;

forming a patterned resist underlayer film by etching the resist underlayer film through the formed resist pattern; and

processing the semiconductor substrate through the patterned resist underlayer film.

### Advantageous Effects of Invention

The resist underlayer film-forming composition contains a reaction product of a hydantoin-containing compound (A) having two epoxy groups with a hydantoin-containing compound (B) different from (A). The resist underlayer film-forming composition can be patterned into a smaller critical resolution size without collapse of the resist pattern after development as compared to a conventional resist underlayer film, thus allowing for the formation of a finer resist pattern. Furthermore, the resist underlayer film-forming composition effectively exhibits good patternability in a wider range of resist pattern sizes than in the conventional art.

### DESCRIPTION OF EMBODIMENTS

A resist underlayer film-forming composition of the present application contains an organic solvent, and a reaction product of a hydantoin-containing compound (A) having two epoxy groups with a hydantoin-containing compound (B) different from (A). The reaction product is preferably a product of a reaction between a secondary amino group of the hydantoin-containing compound (B) and an epoxy group of the hydantoin-containing compound (A). This reaction may be performed by a known method.

Compound (A) is preferably represented by formula (A-1), and compound (B) is preferably represented by formula (B-1):

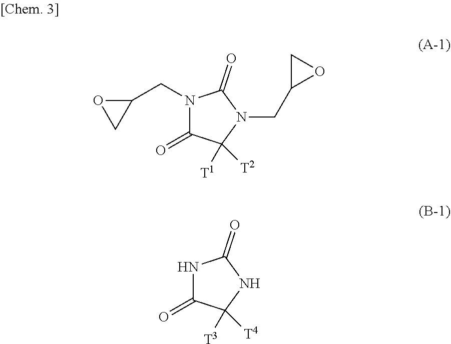

[In formula (A-1) and formula (B-1), T¹, T², T³ and T⁴ each independently denote a hydrogen atom, a C1-C10 alkyl group optionally interrupted by an oxygen atom or a sulfur atom and optionally substituted with a hydroxy group, a C6-C40 aryl group optionally substituted with a hydroxy group, or a C3-C6 alkenyl group.] T¹, T², T³ and T⁴ may be all the same as or different from one another, or some of them may be the same as one another.

In particular, T¹, T², T³ and T⁴ are preferably each a C1-C10 alkyl group or a C6-C40 aryl group.

Examples of the C1-C10 alkyl groups include methyl group, ethyl group, n-propyl group, i-propyl group, cyclopropyl group, n-butyl group, i-butyl group, s-butyl group, t-butyl group, cyclobutyl group, 1-methyl-cyclopropyl group, 2-methyl-cyclopropyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, 2-ethyl-3-methyl-cyclopropyl group and decyl group.

Examples of the C6-C40 aryl groups include phenyl group, o-methylphenyl group, m-methylphenyl group, p-methylphenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, α-naphthyl group, β-naphthyl group, o-biphenylyl group, m-biphenylyl group, p-biphenylyl group, 1-anthryl group, 2-anthryl group, 9-anthryl group, 1-phenanthryl group, 2-phenanthryl group, 3-phenanthryl group, 4-phenanthryl group and 9-phenanthryl group.

Examples of the C3-C6 alkenyl groups include 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group and 3-cyclohexenyl group.

Preferred specific examples of compound (A) include the following compounds.

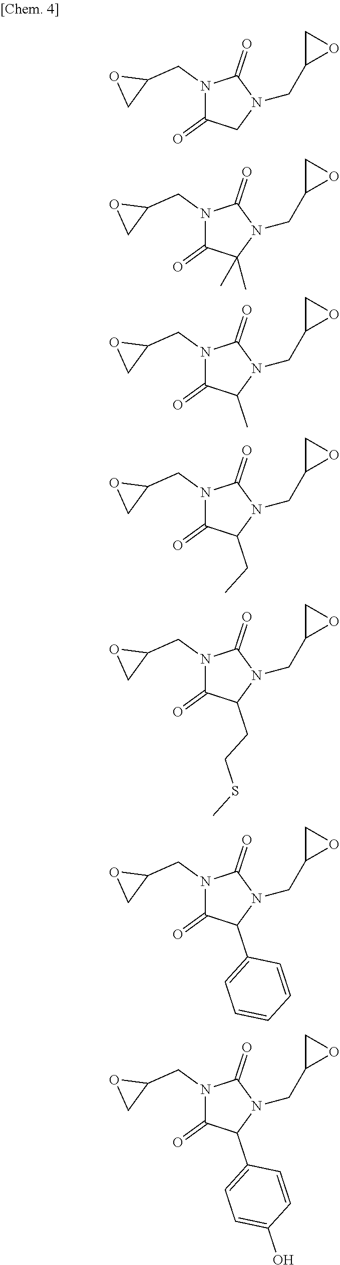

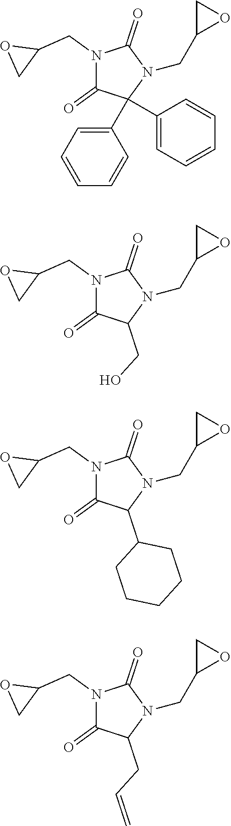 [SMILES: O=C1N(CC2CO2)C(=O)C(c2ccccc2)(c2ccccc2)N1CC1CO1 ; O=C1C(CO)N(CC2CO2)C(=O)N1CC1CO1 ; O=C1C(C2CCCCC2)N(CC2CO2)C(=O)N1CC1CO1 ; C=CCC1C(=O)N(CC2CO2)C(=O)N1CC1CO1]

Preferred specific examples of compound (B) include the following compounds.

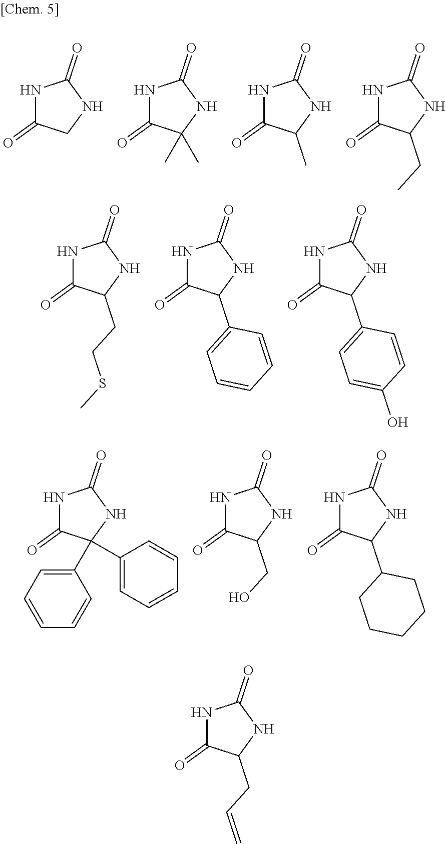

Examples of the organic solvent contained in the resist underlayer film-forming composition of the present invention include ethylene glycol monomethyl ether, ethylene glycol monoethyl ether, methylcellosolve acetate, ethylcellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide and N,N-dimethylacetamide. The solvents may be used each alone or in combination of two or more thereof.

Of the solvents mentioned above, for example, propylene glycol monomethyl ether, propylene glycol monomethyl ether acetate, ethyl lactate, butyl lactate and cyclohexanone are preferable. In particular, propylene glycol monomethyl ether and propylene glycol monomethyl ether acetate are preferable.

The weight average molecular weight of the reaction product is preferably within the range of 500 to 50,000, and more preferably 1,000 to 30,000. For example, the weight average molecular weight may be measured by a gel permeation chromatography method according to Examples.

Preferably, a terminal of the reaction product isl capped with a compound having a functional group.

The functional group is preferably selected from a carboxy group, a hydroxy group, an amino group, an imino group and a thiol group.

The compound having a functional group preferably contains an aliphatic ring optionally interrupted by a heteroatom at a carbon-carbon bond and optionally substituted with a substituent.

The aliphatic ring is preferably a C3-C10 monocyclic or polycyclic aliphatic ring.

The polycyclic aliphatic ring is preferably a bicyclo-ring or a tricyclo-ring.

The aliphatic ring preferably has at least one unsaturated bond.

With regard to the compounds that contain a carboxy group and contain an aliphatic ring optionally interrupted by a heteroatom at a carbon-carbon bond and optionally substituted with a substituent, the disclosure of PCT/JP2020/018436 is incorporated herein by reference.

A structure, in which a terminal of the reaction product of compound (A) with compound (B) is capped with an aliphatic ring optionally interrupted by a heteroatom at a carbon-carbon bond and optionally substituted with a substituent, may be produced by allowing the reaction product of compound (A) and compound (B) to react with any of the carboxy group-containing compounds shown below that contain an aliphatic ring optionally interrupted by a heteroatom at a carbon-carbon bond and optionally substituted with a sub stituent.

Specific examples of the carboxy group-containing compound that contains an aliphatic ring optionally interrupted by a heteroatom at a carbon-carbon bond and optionally substituted with a substituent include compounds shown below. The carboxy group in the following specific examples may be replaced by a hydroxy group, an amino group or a thiol group, and such compounds are also specific examples of the compound.

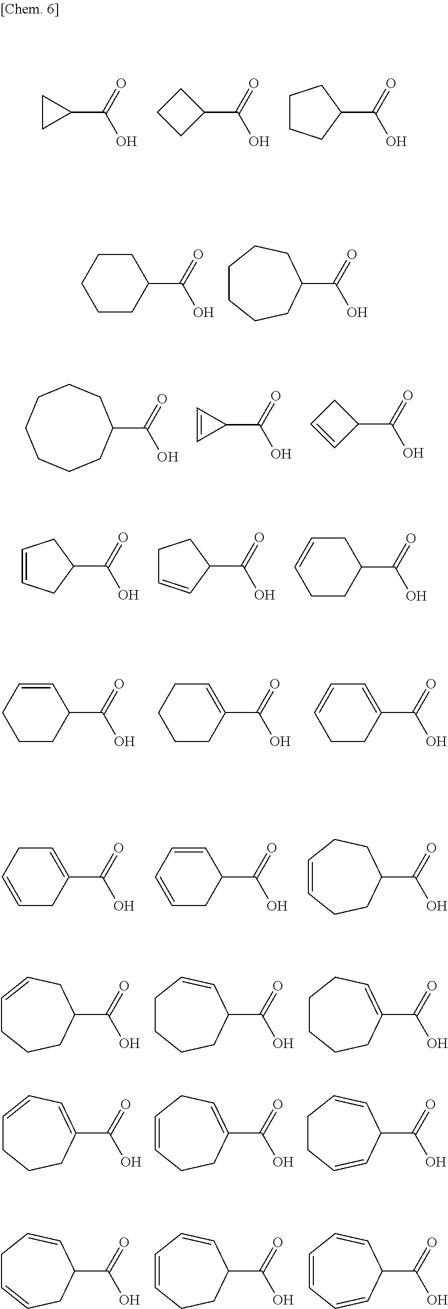

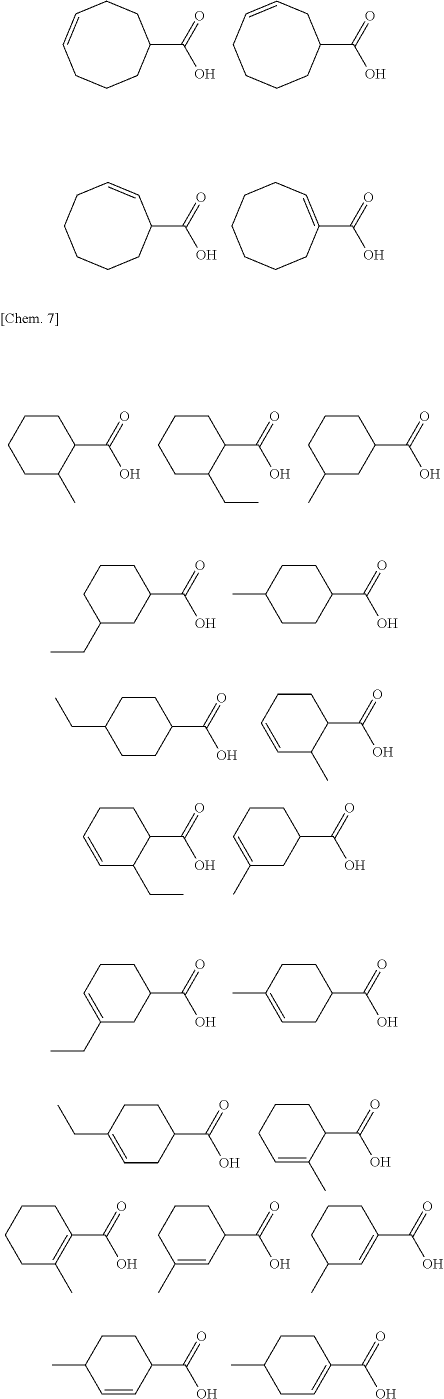

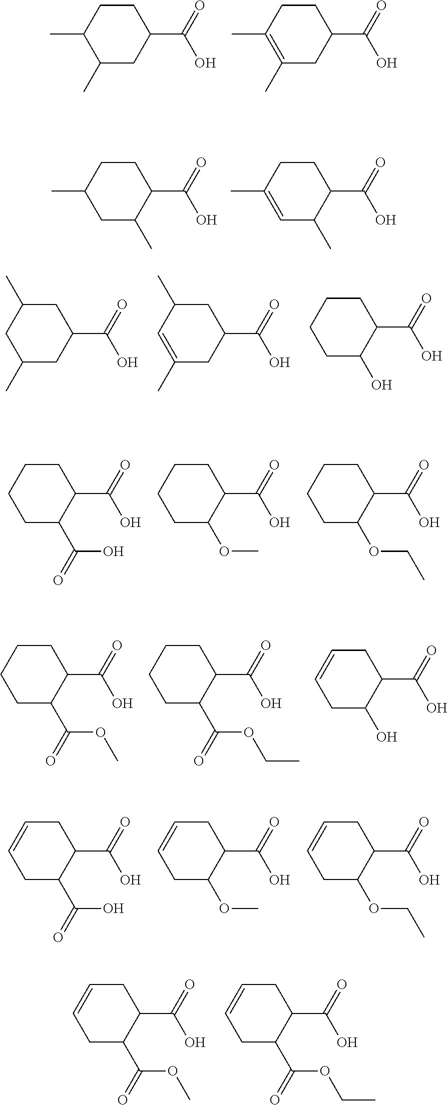

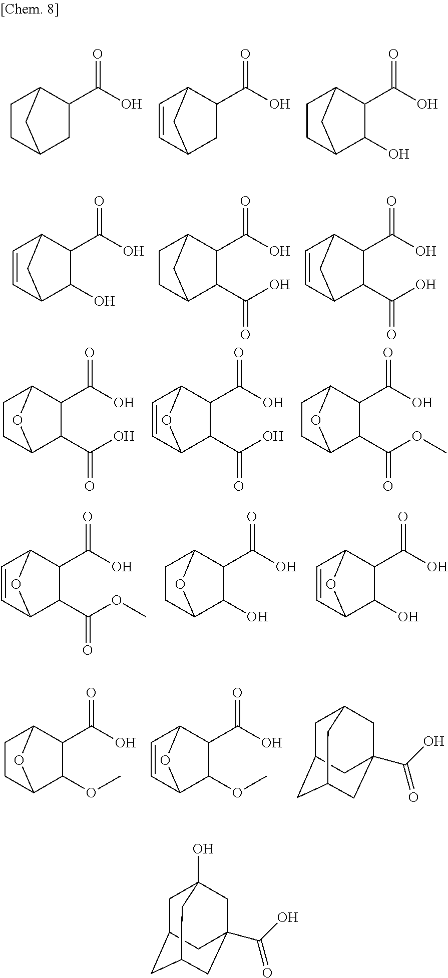

The terminal capped with the compound having a functional group preferably has a structure represented by formula (1) or formula (2) below:

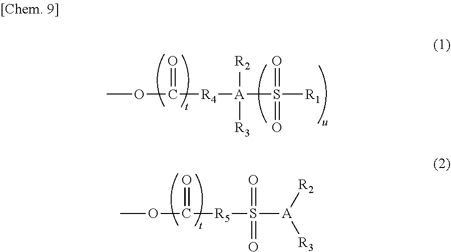

(In formula (1) and formula (2), R₁ denotes an optionally substituted C1-C6 alkyl group, a phenyl group, a pyridyl group, a halogeno group or a hydroxy group; R₂ denotes a hydrogen atom, a C1-C6 alkyl group, a hydroxy group, a halogeno group or an ester group represented by —C(═O)O—X, where X denotes an optionally substituted C1-C6 alkyl group; R₃ denotes a hydrogen atom, a C1-C6 alkyl group, a hydroxy group or a halogeno group; R₄ denotes a direct bond or a C1-C8 divalent organic group; R₅ denotes a C1-C8 divalent organic group; A denotes an aromatic ring or an aromatic heterocyclic ring; t denotes 0 or 1; and u denotes 1 or 2.)

With regard to the terms in formula (1) and formula (2), the disclosure of WO 2015/163195 is incorporated herein by reference.

The terminal structure represented by formula (1) and formula (2) of the reaction product of compound (A) and compound (B) may be produced by allowing the reaction product of compound (A) and compound (B) to react with a compound represented by formula (1a) below and/or a compound represented by formula (2a) below.

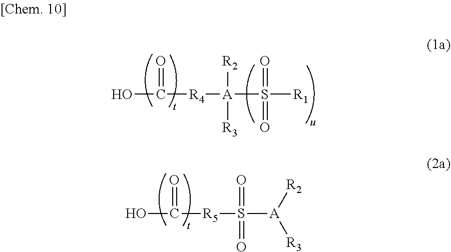

(The symbols in formula (1a) and formula (2a) are as defined in formula (1) and formula (2).)

Examples of the compound represented by formula (1a) include compounds shown below. The carboxy group or hydroxy group in the following specific examples may be replaced by an amino group or a thiol group, and such compounds are also specific examples of the compound.

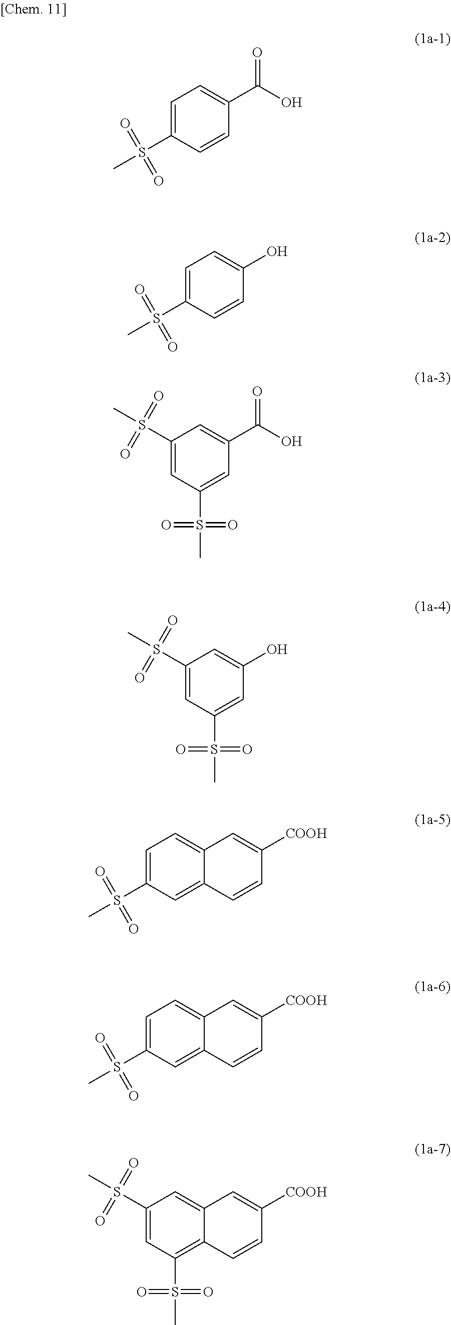

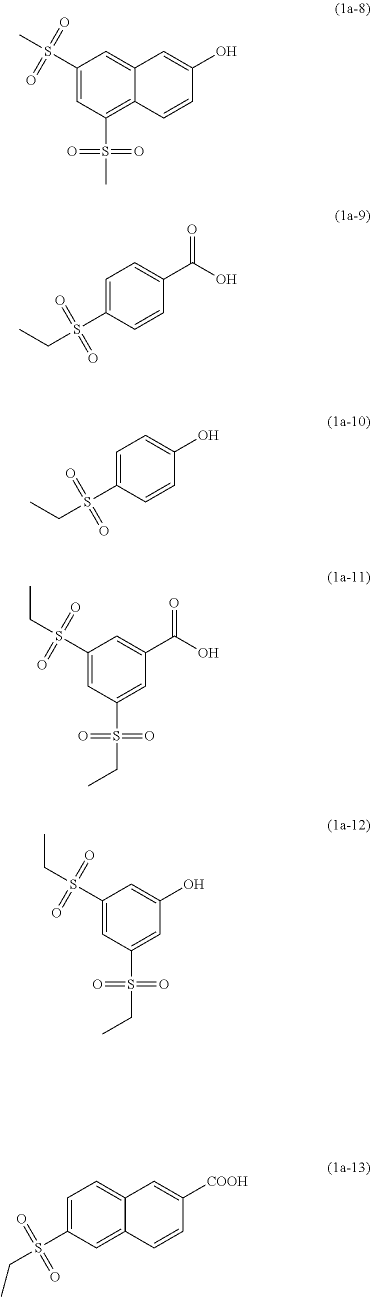 [SMILES: CS(=O)(=O)c1cc(S(C)(=O)=O)c2ccc(O)cc2c1 ; CCS(=O)(=O)c1ccc(C(=O)O)cc1 ; CCS(=O)(=O)c1ccc(O)cc1 ; CCS(=O)(=O)c1cc(C(=O)O)cc(S(=O)(=O)CC)c1 ; CCS(=O)(=O)c1cc(O)cc(S(=O)(=O)CC)c1 ; CCS(=O)(=O)c1ccc2cc(C(=O)O)ccc2c1]

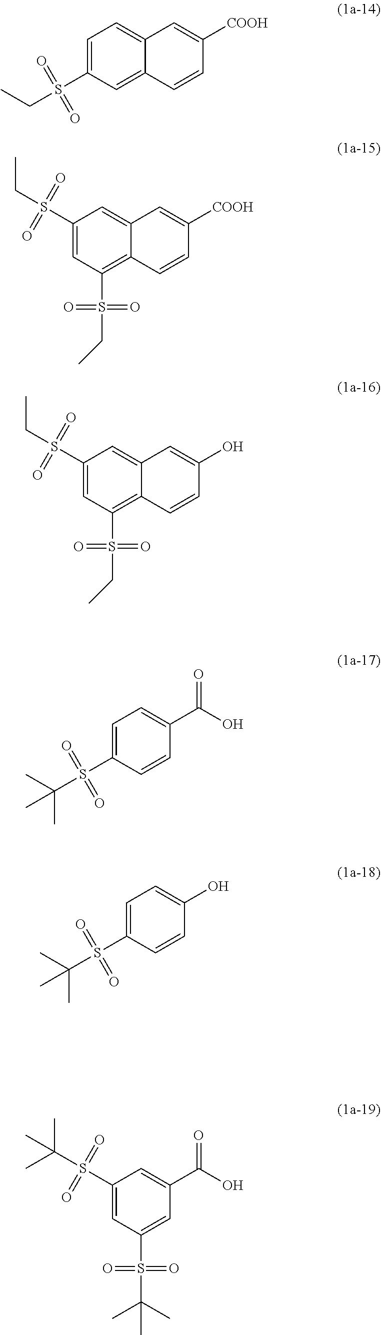 [SMILES: CCS(=O)(=O)c1ccc2cc(C(=O)O)ccc2c1 ; CCS(=O)(=O)c1cc(S(=O)(=O)CC)c2ccc(C(=O)O)cc2c1 ; CCS(=O)(=O)c1cc(S(=O)(=O)CC)c2ccc(O)cc2c1 ; CC(C)(C)S(=O)(=O)c1ccc(C(=O)O)cc1 ; CC(C)(C)S(=O)(=O)c1ccc(O)cc1 ; CC(C)(C)S(=O)(=O)c1cc(C(=O)O)cc(S(=O)(=O)C(C)(C)C)c1]

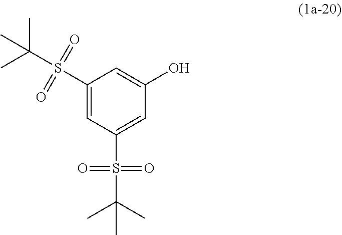 [SMILES: CC(C)(C)S(=O)(=O)c1cc(O)cc(S(=O)(=O)C(C)(C)C)c1]

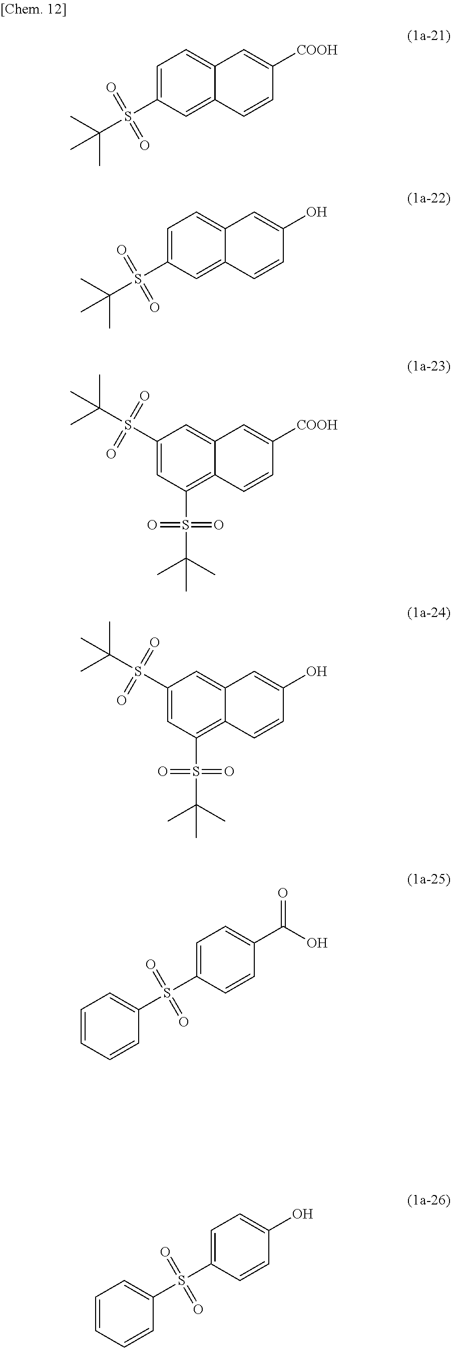 [SMILES: CC(C)(C)S(=O)(=O)c1ccc2cc(C(=O)O)ccc2c1 ; CC(C)(C)S(=O)(=O)c1ccc2cc(O)ccc2c1 ; CC(C)(C)S(=O)(=O)c1cc(S(=O)(=O)C(C)(C)C)c2ccc(C(=O)O)cc2c1 ; CC(C)(C)S(=O)(=O)c1cc(S(=O)(=O)C(C)(C)C)c2ccc(O)cc2c1 ; O=C(O)c1ccc(S(=O)(=O)c2ccccc2)cc1 ; O=S(=O)(c1ccccc1)c1ccc(O)cc1]

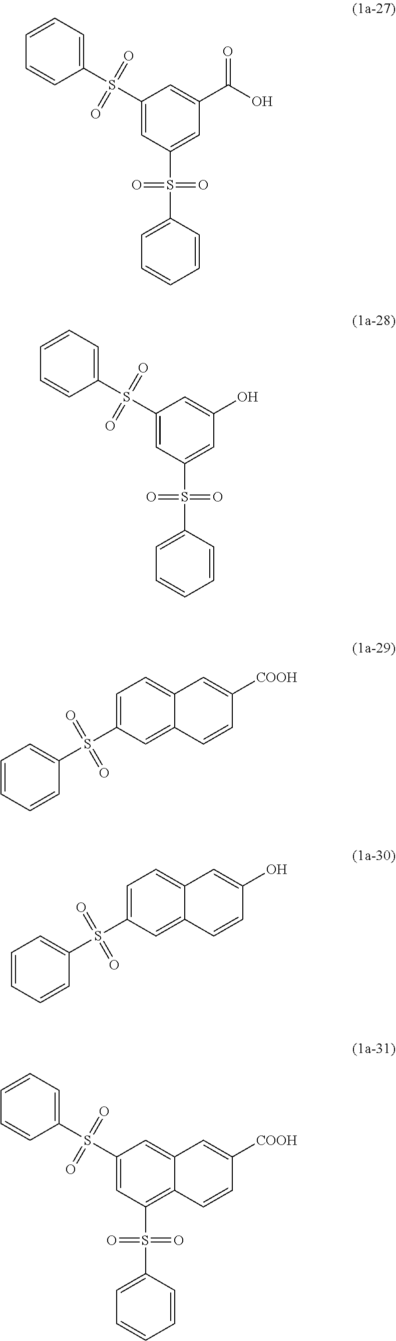 [SMILES: O=C(O)c1cc(S(=O)(=O)c2ccccc2)cc(S(=O)(=O)c2ccccc2)c1 ; O=S(=O)(c1ccccc1)c1cc(O)cc(S(=O)(=O)c2ccccc2)c1 ; O=C(O)c1ccc2cc(S(=O)(=O)c3ccccc3)ccc2c1 ; O=S(=O)(c1ccccc1)c1ccc2cc(O)ccc2c1 ; O=C(O)c1ccc2c(S(=O)(=O)c3ccccc3)cc(S(=O)(=O)c3ccccc3)cc2c1]

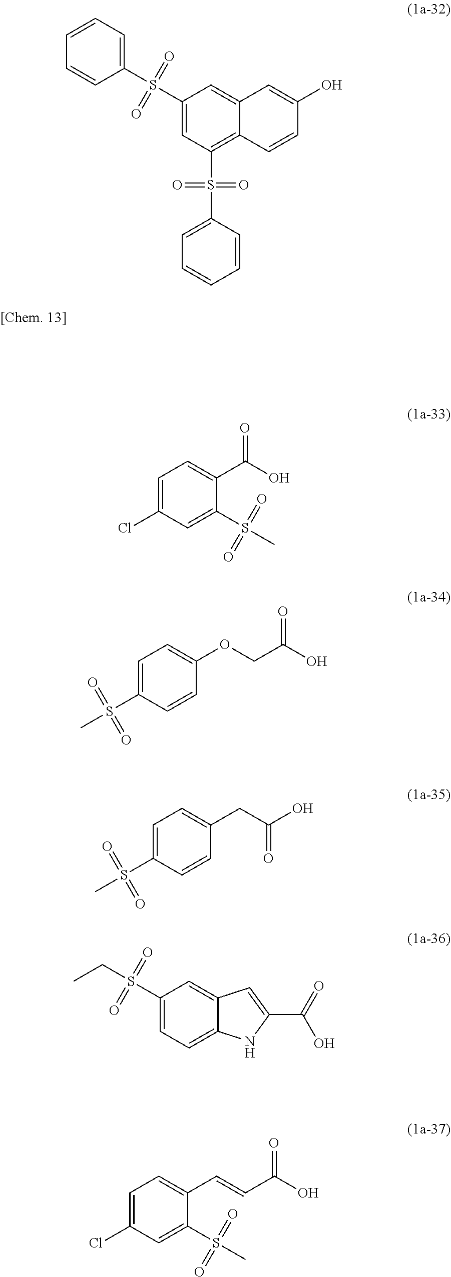 [SMILES: O=S(=O)(c1ccccc1)c1cc(S(=O)(=O)c2ccccc2)c2ccc(O)cc2c1 ; CS(=O)(=O)c1cc(Cl)ccc1C(=O)O ; CS(=O)(=O)c1ccc(OCC(=O)O)cc1 ; CS(=O)(=O)c1ccc(CC(=O)O)cc1 ; CCS(=O)(=O)c1ccc2[nH]c(C(=O)O)cc2c1 ; CS(=O)(=O)c1cc(Cl)ccc1/C=C/C(=O)O]

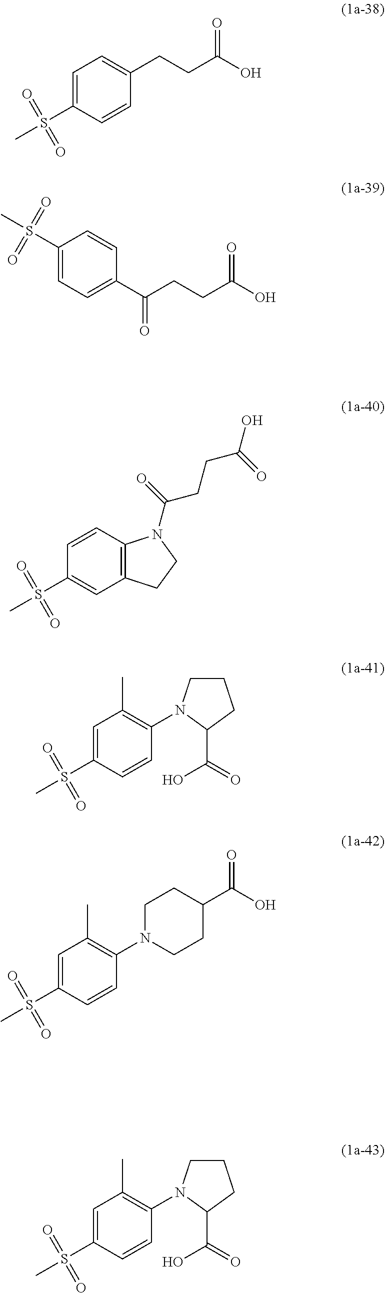 [SMILES: CS(=O)(=O)c1ccc(CCC(=O)O)cc1 ; CS(=O)(=O)c1ccc(C(=O)CCC(=O)O)cc1 ; CS(=O)(=O)c1ccc2c(c1)CCN2C(=O)CCC(=O)O ; Cc1cc(S(C)(=O)=O)ccc1N1CCCC1C(=O)O ; Cc1cc(S(C)(=O)=O)ccc1N1CCC(C(=O)O)CC1 ; Cc1cc(S(C)(=O)=O)ccc1N1CCCC1C(=O)O]

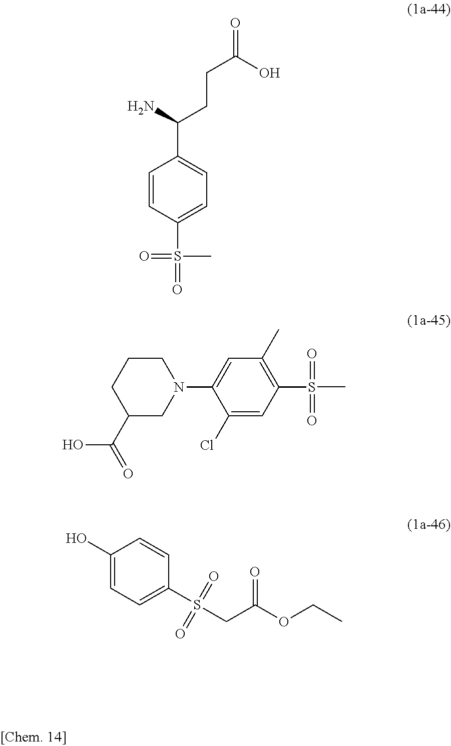 [SMILES: CS(=O)(=O)c1ccc([C@@H](N)CCC(=O)O)cc1 ; Cc1cc(N2CCCC(C(=O)O)C2)c(Cl)cc1S(C)(=O)=O ; CCOC(=O)CS(=O)(=O)c1ccc(O)cc1]

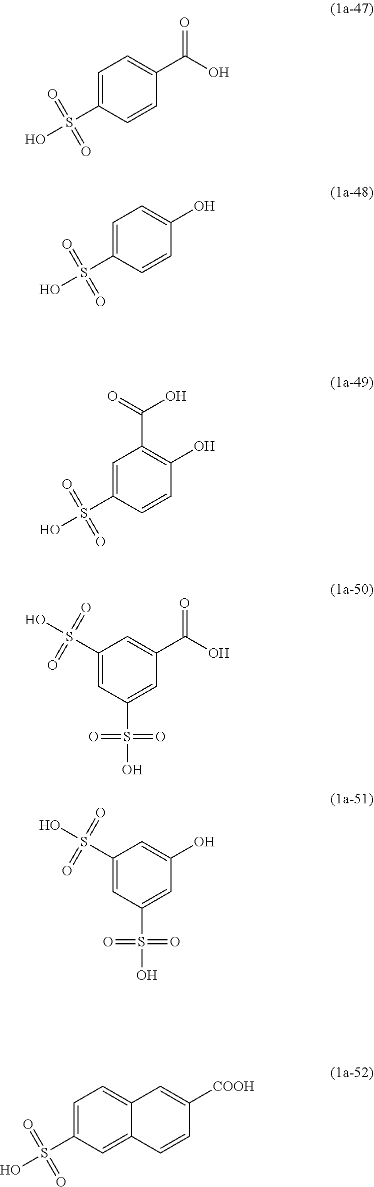 [SMILES: O=C(O)c1ccc(S(=O)(=O)O)cc1 ; O=S(=O)(O)c1ccc(O)cc1 ; O=C(O)c1cc(S(=O)(=O)O)ccc1O ; O=C(O)c1cc(S(=O)(=O)O)cc(S(=O)(=O)O)c1 ; O=S(=O)(O)c1cc(O)cc(S(=O)(=O)O)c1 ; O=C(O)c1ccc2cc(S(=O)(=O)O)ccc2c1]

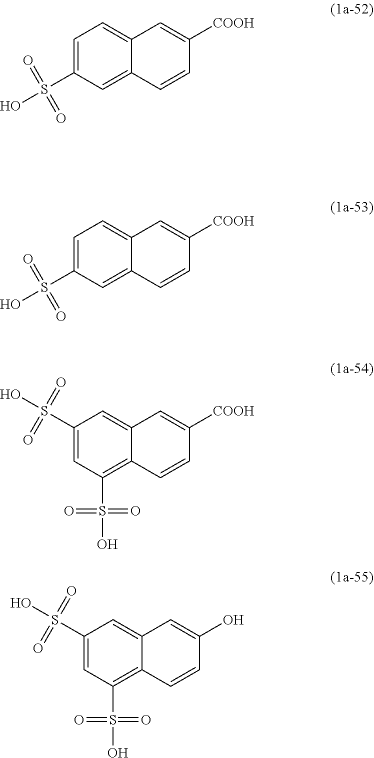 [SMILES: O=C(O)c1ccc2cc(S(=O)(=O)O)ccc2c1 ; O=C(O)c1ccc2cc(S(=O)(=O)O)ccc2c1 ; O=C(O)c1ccc2c(S(=O)(=O)O)cc(S(=O)(=O)O)cc2c1 ; O=S(=O)(O)c1cc(S(=O)(=O)O)c2ccc(O)cc2c1]

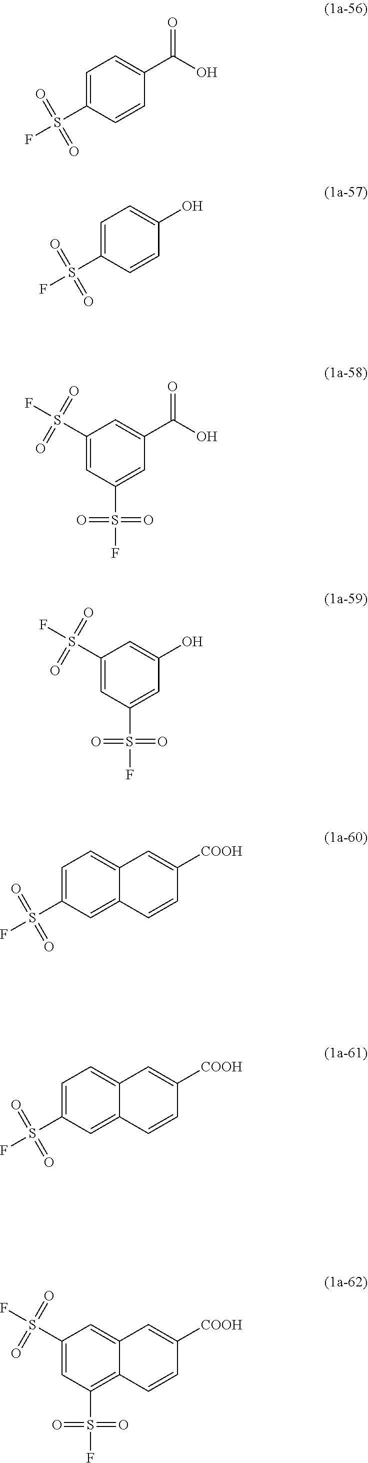

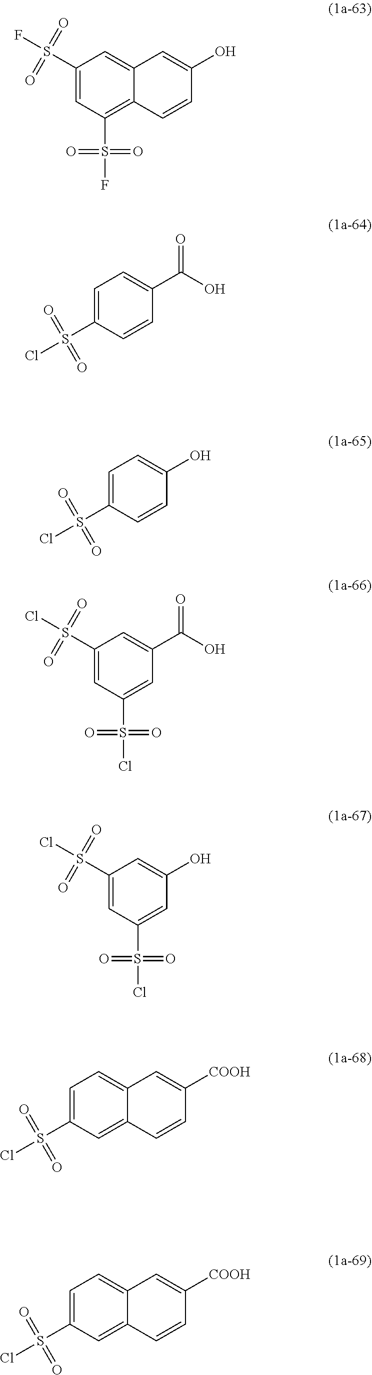

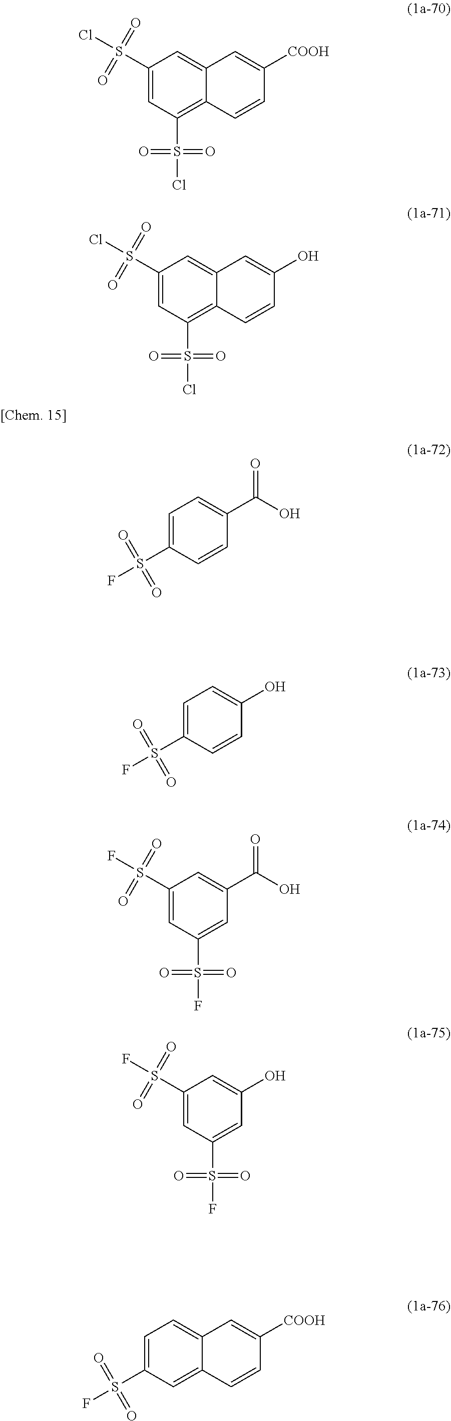

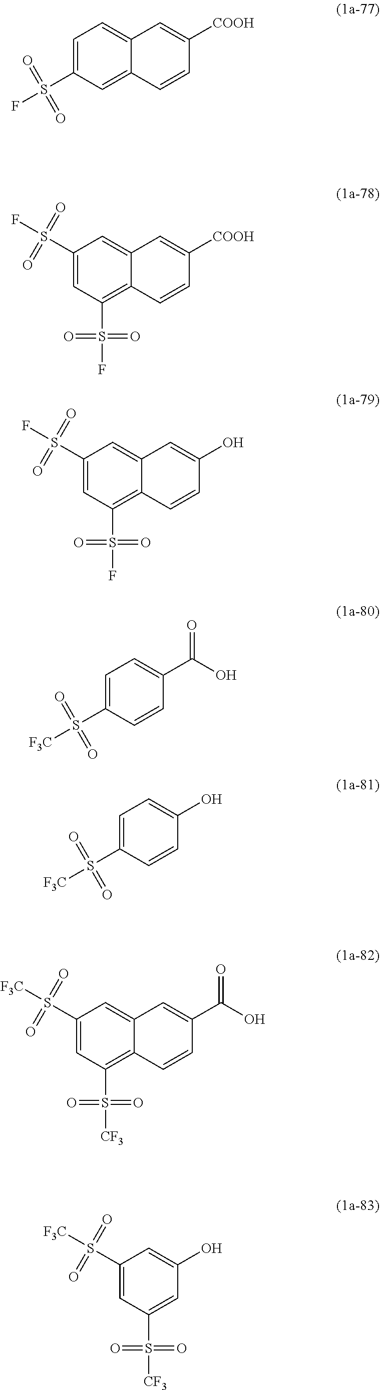

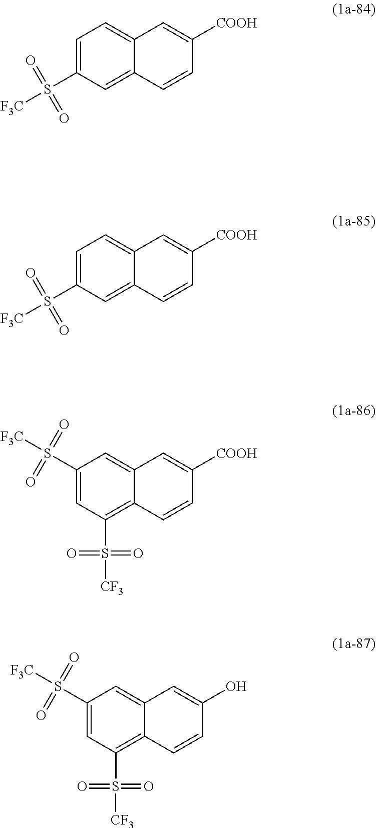 [SMILES: O=C(O)c1ccc2cc(S(=O)(=O)C(F)(F)F)ccc2c1 ; O=C(O)c1ccc2cc(S(=O)(=O)C(F)(F)F)ccc2c1 ; O=C(O)c1ccc2c(S(=O)(=O)C(F)(F)F)cc(S(=O)(=O)C(F)(F)F)cc2c1 ; O=S(=O)(c1cc(S(=O)(=O)C(F)(F)F)c2ccc(O)cc2c1)C(F)(F)F]

Examples of the compound represented by formula (2a) include compounds shown below. The carboxy group in the following specific examples may be replaced by a hydroxy group, an amino group or a thiol group, and such compounds are also specific examples of the compound.

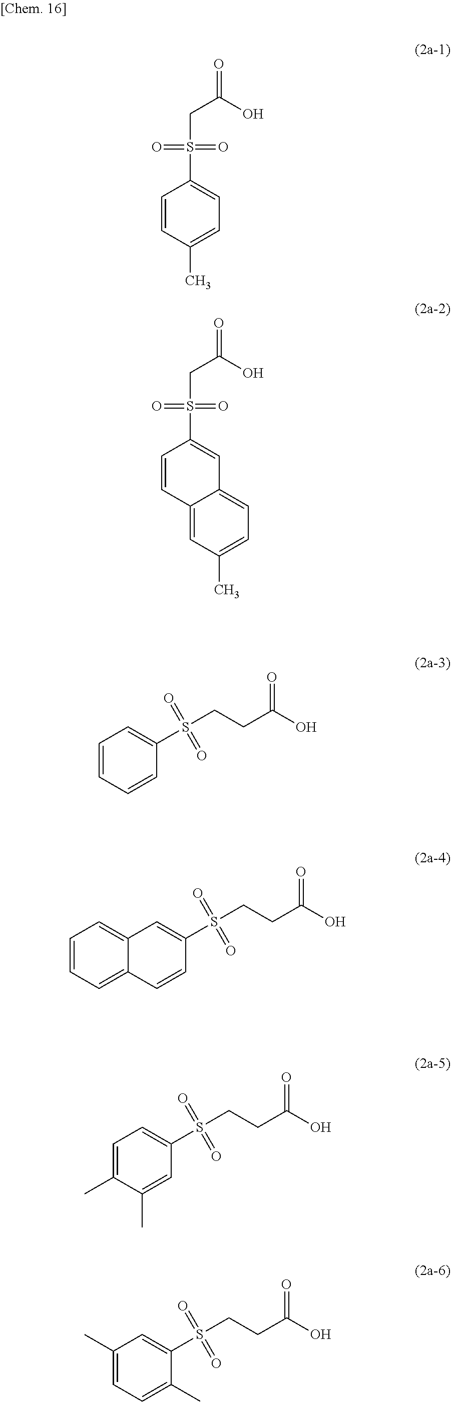 [SMILES: Cc1ccc(S(=O)(=O)CC(=O)O)cc1 ; Cc1ccc2cc(S(=O)(=O)CC(=O)O)ccc2c1 ; O=C(O)CCS(=O)(=O)c1ccccc1 ; O=C(O)CCS(=O)(=O)c1ccc2ccccc2c1 ; Cc1ccc(S(=O)(=O)CCC(=O)O)cc1C ; Cc1ccc(C)c(S(=O)(=O)CCC(=O)O)c1]

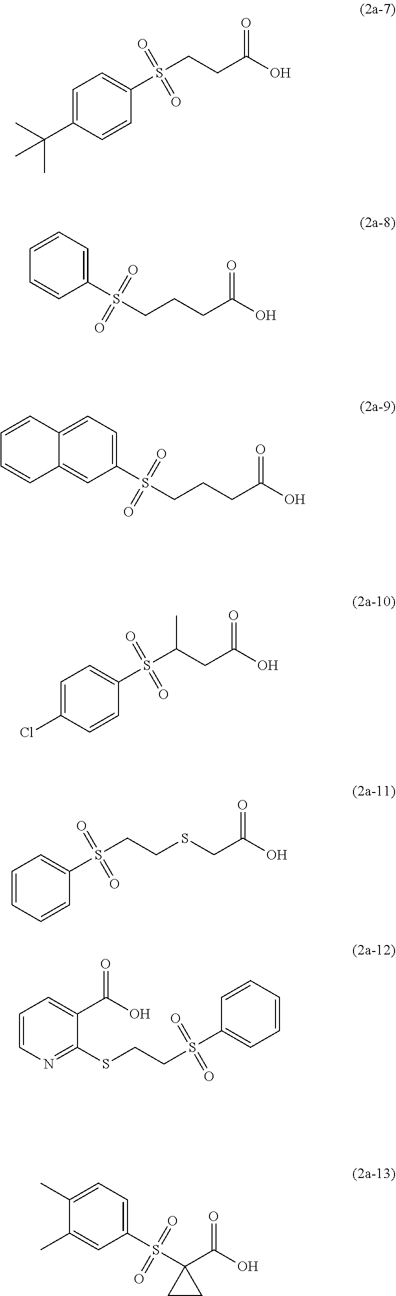

Examples of the compound containing an imino group include the following compounds.

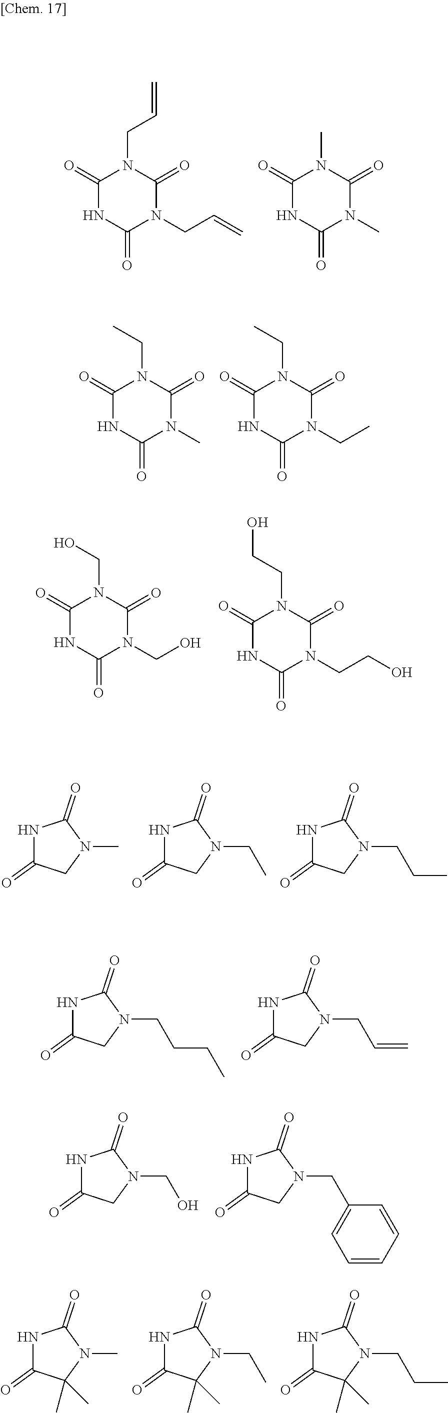

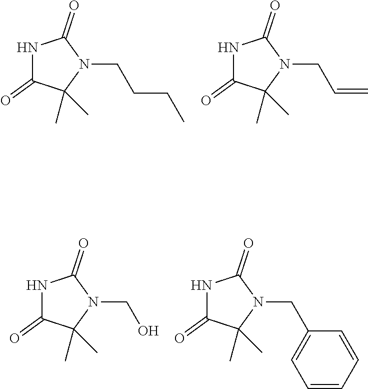

<Acid Generator>

The resist underlayer film-forming composition of the present invention may contain an acid generator as an optional component. Any thermal acid generators and photoacid generators may be used, with thermal acid generators being preferable. Examples of the thermal acid generator include sulfonic acid compounds and carboxylic acid compounds such as p-toluenesulfonic acid, trifluoromethanesulfonic acid, pyridinium-p-toluenesulfonate (pyridinium-p-toluenesulfonic acid), pyridinium-p-hydroxybenzenesulfonic acid (pyridinium p-phenolsulfonate salt), pyridinium-trifluoromethanesulfonic acid, salicylic acid, camphorsulfonic acid, 5-sulfosalicylic acid, 4-chlorobenzenesulfonic acid, 4-hydroxybenzenesulfonic acid, benzenedisulfonic acid, 1-naphthalenesulfonic acid, citric acid, benzoic acid and hydroxybenzoic acid.

Examples of the photoacid generator include onium salt compounds, sulfonimide compounds and disulfonyldiazomethane compounds.

Examples of the onium salt compound include iodonium salt compounds such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate and bis(4-tert-butylphenyl)iodonium trifluoromethanesulfonate, and sulfonium salt compounds such as triphenylsulfonium hexafluoroantimonate, triphenylsulfonium nonafluoro-n-butanesulfonate, triphenylsulfonium camphorsulfonate and triphenylsulfonium trifluoromethanesulfonate.

Examples of the sulfonimide compound include N-(trifluoromethanesulfonyloxy)succinimide, N-(nonafluoro-n-butanesulfonyloxy)succinimide, N-(camphorsulfonyloxy)succinimide and N-(trifluoromethanesulfonyloxy)naphthalimide.

Examples of the disulfonyldiazomethane compound include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane and methylsulfonyl-p-toluenesulfonyldiazomethane.

The acid generators may be used each alone or in combination of two or more thereof.

When an acid generator is used, the content of the acid generator is, for example, within the range of 0.1% by mass to 50% by mass, and preferably 1% by mass to 30% by mass relative to a crosslinking agent described below.

<Crosslinking Agent>

The resist underlayer film-forming composition of the present invention may include a crosslinking agent as an optional component. Examples thereof include hexamethoxymethylmelamine, tetramethoxymethylbenzoguanamine, 1,3,4,6-tetrakis(methoxymethyl)glycoluril (tetramethoxymethylglycoluril) (POWDERLINK [registered trademark] 1174), 1,3,4,6-tetrakis(butoxymethyl)glycoluril, 1,3,4,6-tetrakis(hydroxymethyl)glycoluril, 1,3-bis(hydroxymethyl)urea, 1,1,3,3-tetrakis(butoxymethyl)urea, 1,1,3,3-tetrakis(methoxymethyl)urea and 2,4,6-tris[bis(methoxymethyl)amino]-1,3,5-triazine ((product names) CYMEL [registered trademark]-303, NICALACK [registered trademark] MW-390).

Moreover, the crosslinking agent in the present application may be a nitrogen-containing compound according to WO 2017/187969 that has in the molecule 2 to 6 sub stituents represented by formula (1X) below which are bonded to nitrogen atoms.

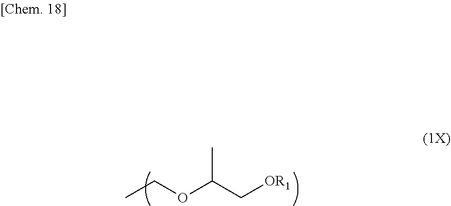

(In formula (1X), R₁ denotes a methyl group or an ethyl group.)

The nitrogen-containing compound that has in the molecule 2 to 6 substituents represented by formula (1X) may be a glycoluril derivative represented by formula (1A) below:

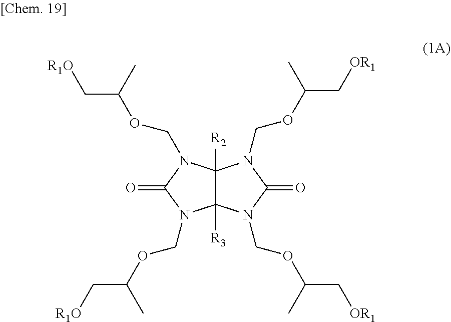

(In formula (1A), the four R₁s each independently denote a methyl group or an ethyl group, and R₂ and R₃ each independently denote a hydrogen atom, a C1-C4 alkyl group or a phenyl group.)

Examples of the glycoluril derivative represented by formula (1A) include the compounds represented by the following formulas (1A-1) to (1A-6):

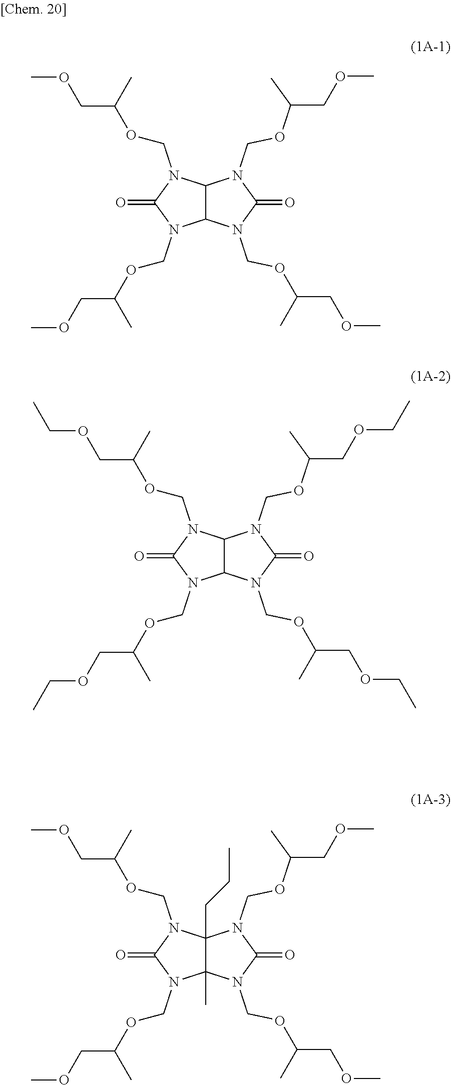

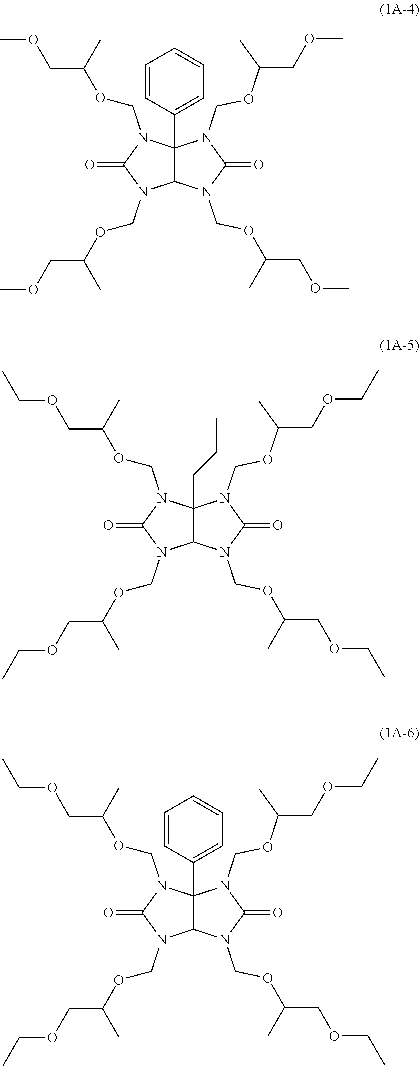

The compound represented by formula (1A) is obtainable by allowing a nitrogen-containing compound that has in the molecule 2 to 6 substituents represented by formula (2X) below which are bonded to nitrogen atoms to react with at least one compound represented by formula (3) below to produce a nitrogen-containing compound that has in the molecule 2 to 6 substituents represented by the above formula (1X).

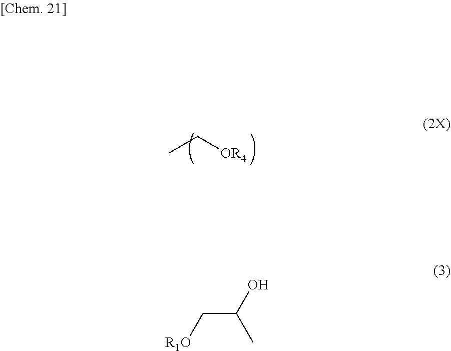

(In formula (2X) and formula (3), R₁ denotes a methyl group or an ethyl group, and R₄ denotes a C1-C4 alkyl group.)

The glycoluril derivative represented by formula (1A) is obtainable by allowing a glycoluril derivative represented by formula (2A) below to react with at least one compound represented by the above formula (3).

For example, the nitrogen-containing compound that has in the molecule 2 to 6 substituents represented by formula (2X) is a glycoluril derivative represented by formula (2A) below:

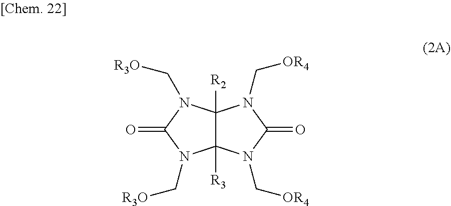

(In formula (2A), R₂ and R₃ each independently denote a hydrogen atom, a C1-C4 alkyl group or a phenyl group, and R₄ independently at each occurrence denotes a C1-C4 alkyl group.)

Examples of the glycoluril derivative represented by formula (2A) include the compounds represented by formulas (2A-1) to (2A-4) below. Moreover, examples of the compound represented by formula (3) include the compounds represented by formulas (3-1) and (3-2) below.

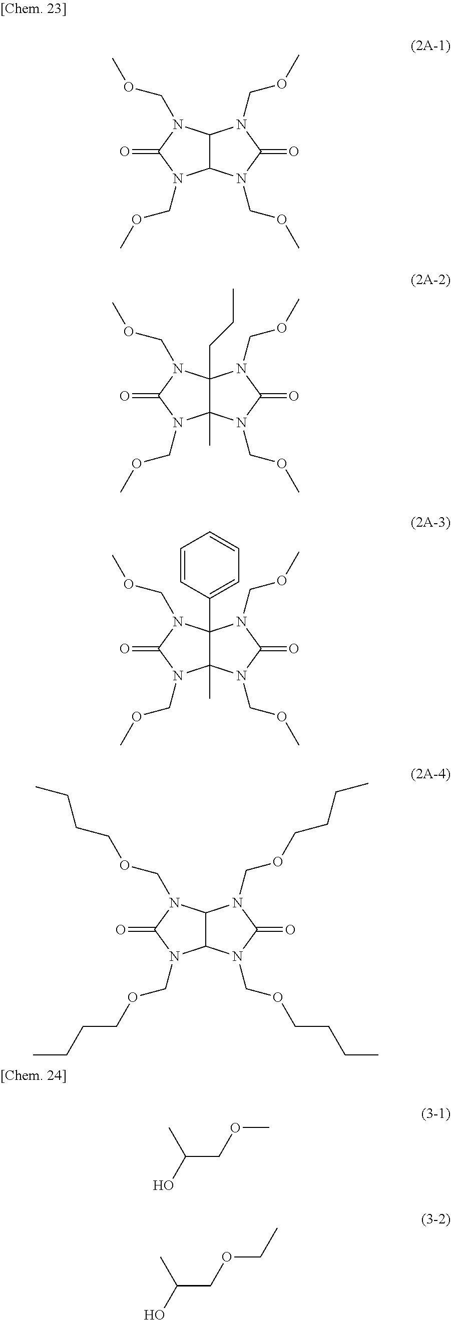

With regard to the details of the nitrogen-containing compound that has in the molecule 2 to 6 substituents represented by formula (1X) which are bonded to nitrogen atoms, the disclosure of WO 2017/187969 is incorporated herein by reference.

When a crosslinking agent is used, the content of the crosslinking agent is, for example, within the range of 1% by mass to 50% by mass, and preferably 5% by mass to 30% by mass relative to the reaction product.

<Additional Components>

To eliminate the occurrence of defects such as pinholes or striation and to further enhance the applicability to surface unevenness, the resist underlayer film-forming composition of the present invention may further contain a surfactant. Examples of the surfactant include nonionic surfactants such as polyoxyethylene alkyl ethers including polyoxyethylene lauryl ether, polyoxyethylene stearyl ether, polyoxyethylene cetyl ether and polyoxyethylene oleyl ether, polyoxyethylene alkylallyl ethers including polyoxyethylene octylphenol ether and polyoxyethylene nonylphenol ether, polyoxyethylene/polyoxypropylene block copolymers, sorbitan fatty acid esters including sorbitan monolaurate, sorbitan monopalmitate, sorbitan monostearate, sorbitan monooleate, sorbitan trioleate and sorbitan tristearate, and polyoxyethylene sorbitan fatty acid esters including polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate, fluorosurfactants such as EFTOP series EF301, EF303 and EF352 (product names, manufactured by Tohkem Products Corp.), MEGAFACE series F171, F173 and R-30 (product names, manufactured by DIC CORPORATION), Fluorad series FC430 and FC431 (product names, manufactured by Sumitomo 3M Limited), AsahiGuard AG710, and Surflon series S-382, SC101, SC102, SC103, SC104, SC105 and SC106 (product names, manufactured by AGC Inc.), and organosiloxane polymer KP341 (manufactured by Shin-Etsu Chemical Co., Ltd.). The amount of the surfactant is usually 2.0% by mass or less, and preferably 1.0% by mass or less of the total solid content of the resist underlayer film-forming composition of the present invention. These surfactants may be used each alone or in combination of two or more thereof.

The resist underlayer film-forming composition of the present application is preferably an electron beam resist underlayer film-forming composition or an EUV resist underlayer film-forming composition used in an electron beam (EB) lithography step and an EUV exposure step, and is preferably an EUV resist underlayer film-forming composition.

<Resist Underlayer Film>

A resist underlayer film of the present invention may be produced by applying the resist underlayer film-forming composition described hereinabove onto a semiconductor substrate and baking the composition.

The resist underlayer film of the present invention is preferably an electron beam resist underlayer film or an EUV resist underlayer film.

Examples of the semiconductor substrate to which the resist underlayer film-forming composition of the present invention is applied include silicon wafers, germanium wafers, and compound semiconductor wafers such as gallium arsenide, indium phosphide, gallium nitride, indium nitride and aluminum nitride.

When a semiconductor substrate having an inorganic film on the surface is used, the inorganic film is formed by ALD (atomic layer deposition), CVD (chemical vapor deposition), reactive sputtering, ion plating, vacuum deposition or spin coating (spin on glass: SOG), for example. Examples of the inorganic film include polysilicon film, silicon oxide film, silicon nitride film, BPSG (boro-phospho silicate glass) film, titanium nitride film, titanium oxynitride film, tungsten film, gallium nitride film and gallium arsenide film.

The resist underlayer film-forming composition of the present invention is applied onto such a semiconductor substrate with an appropriate applicator such as a spinner or a coater. Thereafter, the composition is baked with a heating device such as a hot plate to form a resist underlayer film. The baking conditions are appropriately selected from baking temperatures of 100° C. to 400° C. and amounts of baking time of 0.3 minutes to 60 minutes. Preferably, the baking temperature is 120° C. to 350° C. and the baking time is 0.5 minutes to 30 minutes. More preferably, the baking temperature is 150° C. to 300° C. and the baking time is 0.8 minutes to 10 minutes. If the baking temperature is lower than the range mentioned above, crosslinking would be insufficient. If, on the other hand, the baking temperature is higher than the above range, the resist underlayer film may be decomposed by heat.

The film thickness of the resist underlayer film that is formed is, for example, 0.001 μm (1 nm) to 10 μm, 0.002 μm (2 nm) to 1 μm, 0.005 μm (5 nm) to 0.5 μm (500 nm), 0.001 μm (1 nm) to 0.05 μm (50 nm), 0.002 μm (2 nm) to 0.05 μm (50 nm), 0.003 μm (1 nm) to 0.05 μm (50 nm), 0.004 μm (4 nm) to 0.05 μm (50 nm), 0.005 μm (5 nm) to 0.05 μm (50 nm), 0.003 μm (3 nm) to 0.03 μm (30 nm), 0.003 μm (3 nm) to 0.02 μm (20 nm), or 0.005 μm (5 nm) to 0.02 μm (20 nm).

<Methods for Producing Patterned Substrate, and Method for Manufacturing Semiconductor Device>

A patterned substrate is produced through the following steps. Usually, a patterned substrate is produced by forming a photoresist layer on the resist underlayer film. The photoresist that is formed on the resist underlayer film by application and baking according to a method known per se is not particularly limited as long as the resist is sensitive to the light used for exposure. Any of negative photoresists and positive photoresists may be used, such as positive photoresists composed of a novolak resin and 1,2-naphthoquinonediazide sulfonic acid ester; chemically amplified photoresists composed of a photoacid generator and a binder having a group that is decomposed by an acid to increase the alkali dissolution rate; chemically amplified photoresists composed of an alkali-soluble binder, a photoacid generator and a low-molecular compound that is decomposed by an acid to increase the alkali dissolution rate of the photoresist; chemically amplified photoresists composed of a photoacid generator, a binder having a group that is decomposed by an acid to increase the alkali dissolution rate, and a low-molecular compound that is decomposed by an acid to increase the alkali dissolution rate of the photoresist; and resists containing metal elements. Examples thereof include V146G, product name, manufactured by JSR CORPORATION, APEX-E, product name, manufactured by Shipley, PAR710, product name, manufactured by Sumitomo Chemical Co., Ltd., and AR2772 and SEPR430, product names, manufactured by Shin-Etsu Chemical Co., Ltd. Examples further include fluorine-containing polymer photoresists such as those according to Proc. SPIE, Vol. 3999, 330-334 (2000), Proc. SPIE, Vol. 3999, 357-364 (2000) and Proc. SPIE, Vol. 3999, 365-374 (2000).

Exposure is performed using, for example, i-ray, KrF excimer laser beam, ArF excimer laser beam, EUV (extreme ultraviolet ray) or EB (electron beam) through a mask (a reticle) designed to form a predetermined pattern. The resist underlayer film-forming composition of the present application is preferably used in EUV (extreme ultraviolet ray) or EB (electron beam) exposure, particularly preferably EUV (extreme ultraviolet ray) exposure. An alkaline developer is used for the development, and the conditions are appropriately selected from development temperatures of 5° C. to 50° C. and amounts of development time of 10 seconds to 300 seconds. Examples of the alkaline developer that may be used include aqueous solutions of alkalis such as inorganic alkalis including sodium hydroxide, potassium hydroxide, sodium carbonate, sodium silicate, sodium metasilicate and aqueous ammonia; primary amines including ethylamine and n-propylamine; secondary amines including diethylamine and di-n-butylamine; tertiary amines including triethylamine and methyldiethylamine; alcohol amines including dimethylethanolamine and triethanolamine; quaternary ammonium salts including tetramethylammonium hydroxide, tetraethylammonium hydroxide and choline; and cyclic amines including pyrrole and piperidine. Appropriate amounts of an alcohol such as isopropyl alcohol and a surfactant such as nonionic surfactants may be added to the aqueous alkali solutions described above. Of the developers mentioned above, quaternary ammonium salts are preferable, and tetramethylammonium hydroxide and choline are more preferable. Additional components such as a surfactant may be added to these developers. An organic solvent such as butyl acetate may be used in place of the alkali developer to develop portions of the photoresist that remain low in alkali dissolution rate. A substrate having a pattern of the resist may be produced through the steps described above.

Next, the resist underlayer film is dry-etched using as a mask the formed resist pattern. When the inorganic film described hereinabove is present on the surface of the semiconductor substrate that is used, the etching process exposes the surface of the inorganic film. When there is no inorganic film on the surface of the semiconductor substrate that is used, the etching process exposes the surface of the semiconductor substrate. The substrate is then processed by a method known per se (such as a dry etching method). A semiconductor device may be thus manufactured.

### Examples

The present invention will be explained in detail by referring to Examples and Comparative Examples below. However, it should be construed that the scope of the present invention is not limited to the examples below.

The weight average molecular weight (Mw) of polymers (A) according to Synthesis Examples below is the results measured by a gel permeation chromatography (GPC) method. The measurement was performed using a GPC device manufactured by TOSOH CORPORATION under the following measurement conditions.

Measurement device: HLC-8020GPC [product name] (manufactured by TOSOH CORPORATION)

GPC columns: TSKgel G2000HXL: two columns; G3000HXL: one column; G4000HXL: one column [product names] (all manufactured by TOSOH CORPORATION)

Column temperature: 40° C.

Solvent: Tetrahydrofuran (THF)

Flow rate: 1.0 ml/min

Standard samples: Polystyrenes (manufactured by TOSOH CORPORATION)

### [Synthesis Example 1] Synthesis of Reaction Product 1

4.91 g of N,N-diglycidyl-5,5-dimethylhydantoin, 2.83 g of 5,5-dimethylhydantoin and 0.27 g of tetrabutylphosphonium bromide were added to and dissolved in 12.00 g of propylene glycol monomethyl ether. The reaction vessel was purged with nitrogen, and the reaction was performed by heating under reflux for 24 hours to obtain a reaction product 1 solution. GPC analysis showed that the reaction product 1 in the obtained solution had a weight average molecular weight of 1,400 relative to standard polystyrenes.

The reaction product 1 contains the following structure as a repeating unit structure.

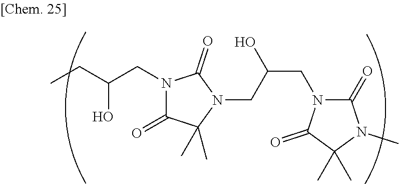

### [Synthesis Example 2] Synthesis of Reaction Product 2

4.00 g of N,N-diglycidyl-5,5-dimethylhydantoin, 3.71 g of 5-phenylhydantoin and 0.30 g of tetrabutylphosphonium bromide were added to and dissolved in 12.00 g of propylene glycol monomethyl ether. The reaction vessel was purged with nitrogen, and the reaction was performed by heating under reflux for 24 hours to obtain a reaction product 2 solution. GPC analysis showed that the reaction product 2 in the obtained solution had a weight average molecular weight of 3,500 relative to standard polystyrenes.

The reaction product 2 contains the following structure as a repeating unit structure.

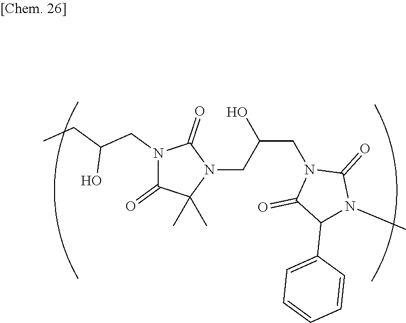

### [Synthesis Example 3] Synthesis of Reaction Product 3

3.66 g of N,N-diglycidyl-5,5-dimethylhydantoin, 4.15 g of 5,5-diphenylhydantoin and 0.20 g of tetrabutylphosphonium bromide were added to and dissolved in 12.00 g of propylene glycol monomethyl ether. The reaction vessel was purged with nitrogen, and the reaction was performed by heating under reflux for 24 hours to obtain a reaction product 3 solution. GPC analysis showed that the reaction product 3 in the obtained solution had a weight average molecular weight of 3,100 relative to standard polystyrenes.

The reaction product 3 contains the following structure as a repeating unit structure.

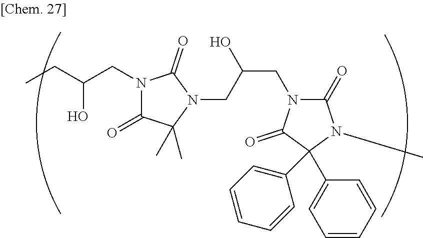

### [Synthesis Example 4] Synthesis of Reaction Product 4

4.52 g of N,N-diglycidyl-5,5-dimethylhydantoin, 2.97 g of 5-phenylhydantoin, 1.17 g of 3-hydroxy-1-adamantanecarboxylic acid and 0.34 g of tetrabutylphosphonium bromide were added to and dissolved in 11.00 g of propylene glycol monomethyl ether. The reaction vessel was purged with nitrogen, and the reaction was performed by heating under reflux for 24 hours to obtain a reaction product 4 solution. GPC analysis showed that the reaction product 4 in the obtained solution had a weight average molecular weight of 2,400 relative to standard polystyrenes.

The reaction product 4 contains the following structure as a repeating unit structure.

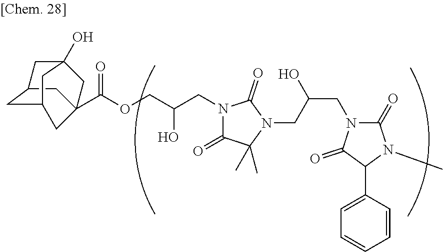

### [Synthesis Example 5] Synthesis of Reaction Product 5

4.01 g of N,N-diglycidyl-5,5-dimethylhydantoin, 2.64 g of 5-phenylhydantoin, 1.06 g of 4-(methylsulfonyl)benzoic acid and 0.30 g of tetrabutylphosphonium bromide were added to and dissolved in 12.00 g of propylene glycol monomethyl ether. The reaction vessel was purged with nitrogen, and the reaction was performed by heating under reflux for 24 hours to obtain a reaction product 5 solution. GPC analysis showed that the reaction product 5 in the obtained solution had a weight average molecular weight of 1,900 relative to standard polystyrenes.

The reaction product 5 contains the following structure as a repeating unit structure.

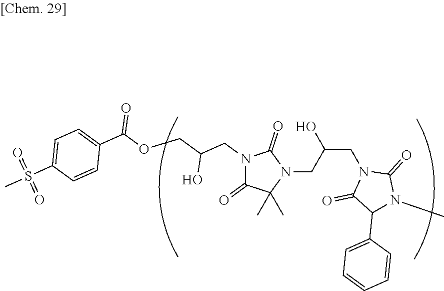

### [Synthesis Example 6] Synthesis of Reaction Product 6

4.62 g of N,N-diglycidyl-5,5-dimethylhydantoin, 3.04 g of 5-phenylhydantoin, 1.06 g of 5-norbornene-2,3-dicarboxylic anhydride and 0.34 g of tetrabutylphosphonium bromide were added to and dissolved in 11.00 g of propylene glycol monomethyl ether. The reaction vessel was purged with nitrogen, and the reaction was performed by heating under reflux for 24 hours to obtain a reaction product 6 solution. GPC analysis showed that the reaction product 6 in the obtained solution had a weight average molecular weight of 2,100 relative to standard polystyrenes.

The reaction product 6 contains the following structure as a repeating unit structure.

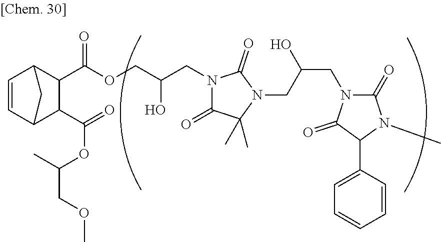

### Comparative Synthesis Example 1

8.00 g of monoallyl diglycidyl isocyanuric acid, 5.45 g of barbital and 0.48 g of tetrabutylphosphonium bromide were added to and dissolved in 56.00 g of propylene glycol monomethyl ether. The reaction vessel was purged with nitrogen, and the reaction was performed by heating under reflux for 10 hours to obtain a reaction product 7 solution. GPC analysis showed that the reaction product 7 in the obtained solution had a weight average molecular weight of 10,000 relative to standard polystyrenes.

The reaction product 7 contains the following structure as a repeating unit structure.

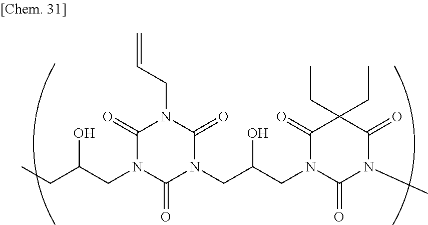

### Comparative Synthesis Example 2

3.66 g of N,N-diglycidyl-5,5-dimethylhydantoin, 5.45 g of barbital and 0.48 g of tetrabutylphosphonium bromide were added to and dissolved in 56.00 g of propylene glycol monomethyl ether. The reaction vessel was purged with nitrogen, and the reaction was performed by heating under reflux for 10 hours to obtain a reaction product 8 solution. GPC analysis showed that the reaction product 8 in the obtained solution had a weight average molecular weight of 4,000 relative to standard polystyrenes.

The reaction product 8 contains the following structure as a repeating unit structure.

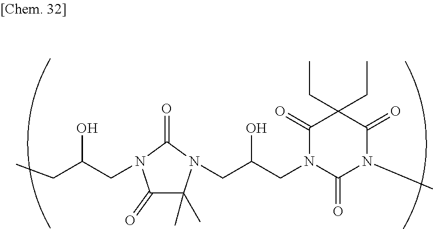

### Example 1

3.12 g of the solution obtained in Synthesis Example 1 that contained 0.047 g of the reaction product 1 was mixed together with 0.11 g of tetramethoxymethyl glycoluril and 0.012 g of pyridinium p-phenolsulfonate salt. The materials were dissolved by adding thereto 263.41 g of propylene glycol monomethyl ether and 29.89 g of propylene glycol monomethyl ether acetate. The resultant solution was filtered through a polyethylene microfilter having a pore size of 0.05 μm, to prepare a resist underlayer film-forming composition.

### Examples 2 to 6

Resist underlayer film-forming compositions were prepared in the same manner as in Example 1, except that the reaction product 1 was replaced by each of the reaction products 2 to 6.

### Comparative Examples 1 and 2

Resist underlayer film-forming compositions were prepared in the same manner as in Example 1, except that the reaction product 1 was replaced by each of the reaction products 7 and 8.

(Resist Patterning Evaluation)

[Test of Formation of Resist Pattern with Electron Beam Lithography System]

Each of the resist underlayer film-forming compositions was applied onto a silicon wafer using a spinner. Each of the silicon wafers was baked on a hot plate at 205° C. for 60 seconds to form a resist underlayer film having a film thickness of 5 nm. On each of the resist underlayer films was spin-coated an EUV negative resist solution (containing a methacrylic polymer), and the coating was heated at 100° C. for 60 seconds to form an EUV resist film. The resist film was exposed under the predetermined conditions using an electron beam lithography system (ELS-G130). After the exposure, baking (PEB) was performed at 100° C. for 60 seconds. The resist film was then cooled to room temperature on a cooling plate and was developed with butyl acetate, to subsequently form a resist pattern having a pillar size of 17 nm to 28 nm. For the length measurement of the resist pattern, a scanning electron microscope (CG4100 manufactured by Hitachi High-Tech Corporation) was used.

The photoresist patterns thus obtained were observed from the upper side of the pattern to determine the minimum CD size free from collapse (falling) within the shot of the resist pattern and the maximum CD size free from connection (bridge) between adjacent patterns, thereby determining the range within which the pattern was well resolved. While it can be said that the larger this range, the wider the pattern range within which a good pattern is formed, Examples 1 to 6 demonstrated that they provided a wider size range within which a good pattern could be formed than did Comparative Examples 1 and 2.

Table 1 shows the results of observation of the resist patterns in Examples 1 to 6 and Comparative Examples 1 and 2.

TABLE 1

| | Range of patternable resolution sizes |
|---|---|
| | ((Bridge-free maximum size)- |
| | (Collapse-free minimum size)) |
| Ex. 1 | 5.3 nm |
| Ex. 2 | 6.6 nm |
| Ex. 3 | 6.0 nm |
| Ex. 4 | 6.0 nm |
| Ex. 5 | 6.4 nm |
| Ex. 6 | 6.9 nm |
| Comp. Ex. 1 | 3.7 nm |
| Comp. Ex. 2 | 5.0 nm |

### INDUSTRIAL APPLICABILITY

The resist underlayer film-forming composition according to the present invention is a composition for forming a resist underlayer film that allows a desired resist pattern to be formed. The resist underlayer film-forming composition is useful in a method for producing a resist-patterned substrate, and a method for manufacturing a semiconductor device.

1. A resist underlayer film-forming composition comprising:
an organic solvent; and
a reaction product of:
(A) a hydantoin-containing compound having two epoxy groups, with (B) a hydantoin-containing compound different from (A).

2. The resist underlayer film-forming composition according to claim 1, wherein the reaction product is a product of a reaction between a secondary amino group of the hydantoin-containing compound (B) and an epoxy group of the hydantoin-containing compound (A).

3. The resist underlayer film-forming composition according to claim 1, wherein compound (A) is represented by formula (A-1), and compound (B) is represented by formula (B-1): 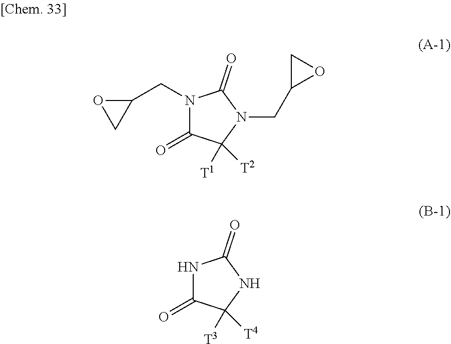
[in formula (A-1) and formula (B-1), T¹, T², T³ and T⁴ each independently denote a hydrogen atom, a C1-C10 alkyl group optionally interrupted by an oxygen atom or a sulfur atom and optionally substituted with a hydroxy group, a C6-C40 aryl group optionally substituted with a hydroxy group, or a C3-C6 alkenyl group].

4. The resist underlayer film-forming composition according to claim 1, wherein the reaction product has a terminal capped with a compound having a functional group.

5. The resist underlayer film-forming composition according to claim 4, wherein the functional group is selected from a carboxy group, a hydroxy group, an amino group, an imino group and a thiol group.

6. The resist underlayer film-forming composition according to claim 4, wherein the compound having a functional group contains an aliphatic ring optionally interrupted by a heteroatom at a carbon-carbon bond and optionally substituted with a substituent.

7. The resist underlayer film-forming composition according to claim 4, wherein the terminal capped with the compound having a functional group has a structure represented by formula (1) and formula (2): 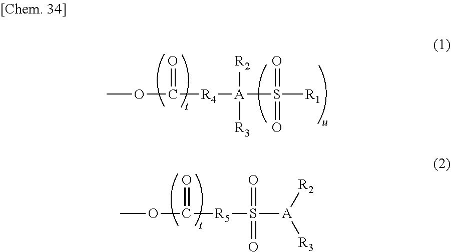
(in formula (1) and formula (2), R₁ denotes an optionally substituted C1-C6 alkyl group, a phenyl group, a pyridyl group, a halogeno group or a hydroxy group; R₂ denotes a hydrogen atom, a C1-C6 alkyl group, a hydroxy group, a halogeno group or an ester group represented by —C(═O)O—X, where X denotes an optionally substituted C1-C6 alkyl group; R₃ denotes a hydrogen atom, a C1-C6 alkyl group, a hydroxy group or a halogeno group; R₄ denotes a direct bond or a C1-C8 divalent organic group; R₅ denotes a C1-C8 divalent organic group; A denotes an aromatic ring or an aromatic heterocyclic ring; t denotes 0 or 1; and u denotes 1 or 2).

8. The resist underlayer film-forming composition according to claim 1, further comprising an acid generator.

9. The resist underlayer film-forming composition according to claim 1, further comprising a crosslinking agent.

10. The resist underlayer film-forming composition according to claim 1, which is an electron beam or EUV resist underlayer film-forming composition.

11. A resist underlayer film comprising a baked product of a coating film comprising the resist underlayer film-forming composition according to claim 1.

12. A method for producing a patterned substrate, comprising the steps of:
applying the resist underlayer film-forming composition according to claim 1 onto a semiconductor substrate followed by baking to form a resist underlayer film;
applying a resist onto the resist underlayer film followed by baking to form a resist film;
exposing the semiconductor substrate coated with the resist underlayer film and the resist; and
developing the exposed resist film followed by patterning.

13. A method for manufacturing a semiconductor device, comprising the steps of:
forming on a semiconductor substrate a resist underlayer film comprising the resist underlayer film-forming composition according to claim 1;
forming a resist film on the resist underlayer film;
forming a resist pattern by applying a light or electron beam to the resist film followed by development;
forming a patterned resist underlayer film by etching the resist underlayer film through the formed resist pattern; and
processing the semiconductor substrate through the patterned resist underlayer film.
